(19) United States
(12) Patent Application Publication
(10) Pub. No.: US 2006/0220010 A1
(43) Pub. Date: Oct. 5, 2006

(54) Organic light emitting diode display

(75) Inventors: Wan-Yu Wang, Hsinchu City (TW); Chih-Hung Su, Hsinchu City (TW)

Correspondence Address: BIRCH STEWART KOLASCH & BIRCH, PO BOX 747, FALLS CHURCH, VA, 22040-0747, US

(73) Assignee: AU Optronics Corp.

(21) Appl. No.: 11/348,453

(22) Filed: Feb. 7, 2006

(30) Foreign Application Priority Data
Mar. 29, 2005 (TW) 94109841

(51) Int. Cl. H01L 29/08; H01L 33/00

(52) U.S. Cl. 257/40; 257/86; 257/E51.022

(57) ABSTRACT

An organic light emitting diode display includes a substrate, an electroluminescence device fabricated on the lower surface of the substrate, a back plate, and a metal pattern formed on the surface of the back plate facing the substrate and contacted with the cathode of the electroluminescence device.

### FIELD OF THE INVENTION

The present invention relates to an organic light emitting diode (OLED) display, and more specifically to a structure for encapsulating the display.

### BACKGROUND OF THE INVENTION

An organic electroluminescence display can also be called an OLED display. The OLED display can substitute for the liquid crystal display (LCD) for its superiority in high brightness, quick response time, less weight and size, high contrast ratio, enhanced color saturation, wide viewing angle, and low power consumption. Recently in the market, the OLED displays have been widely applied to various portable electronic products, such as mobile phones, PDAs, and laptops.

A major difference between the OLED display and the LCD is the luminous method. The light source of OLED display is a self-luminous emission layer. FIG. 1 shows schematically a conventional org anic light emitting diode (OLED) structure, which comprises an anode electrode plate 12, an emission layer (organic layer) 14, and a cathode electrode plate 16. The emission layer 14 was interposed between the anode electrode plate 12 and the cathode electrode plate 16 so as to form a so-called sandwich structure. When a positive driving voltage is applied, holes are injected from the anode electrode plate 12 to the emission layer 14, and electrons are injected from the cathode electrode plate 16 into the emission layer 14. The holes and the electrons are coupled in the emission layer 14 to stimulate the electron of organic material to higher energy level which is called excited states, and then the electrons turn from excited states into base states and simultaneously radiate light from the energy drops.

In general, when the OLED 1 is influenced by moisture, some severe problems may occur subsequently. Firstly, the moisture may attach both the surface and inside of the emission layer 14 so as to reduce the intensity and the uniformity of the light. Secondly, the moisture may be sucked into the interface between the emission layer 14 and the electrode plate 12 or 16, and may thus cause the emission layer 14 to peel off from the electrodes 12 or 16, such that dark spots on the display may be seen. To prevent the surrounding moisture from damaging the OLED 1, a sealed encapsulating structure is usually used to protect the OLED 1.

FIG. 2 shows a typical structure of the OLED according to the prior art. The structure 20 as shown comprises an organic light emitting diode (OLED) 1, a glass substrate 22 with circuits formed on it, and a back plate or cover glass 24. The OLED 1 is fabricated on the lower surface of the substrate 22. On the upper surface of the back plate 24, a wide fillister 241 is formed by sandblasting or etching. The substrate 22 is mounted onto the back plate 24 by an encircling adhesive 26 outside the fillister 241 (i.e. around the edge of the back plate 24). The fillister 241 of the back plate 24 provides a cavity to better accommodate the OLED 1 in the space between the substrate 22 and the back plate 24.

In a conventional structure shown in FIG. 2, the cavity (i.e. the fillister 241) can also accommodate some desiccant materials 28 for absorbing residual moisture and oxygen. The desiccant materials 28 can be placed over the surface of the fillister 241a for absorbing the interior moisture to prevent possible breakage of the OLED 1.

While the aforesaid structure 20 is effective to prevent breakage of the OLED 1 caused by the moisture, there are some defects as follows. Firstly, the cavity should have enough depth to accommodate the desiccant materials 28, and so the back plate 24 shall have a thickness large enough to process such a fillister 241. Definitely, under this requirement, the thickness of the structure 20 cannot be reduced. Secondly, the fillister 241 must have a broad and uniform surface 241a, and therefore the machining of the fillister 241 shall take a long time and thus usually meets control difficulty. Because the production cost of the back plate 24 cannot be reduced, its strength against the possible breakage cannot be increased. Thirdly, when the display is made bigger, bending phenomenon by the gravity in both the glass substrate 22 and the back plate 24 becomes significant. In a severe situation, the back plate 24 or the substrate 22 may deflect to affect the operation of the cathode electrode 16 and the emission layer 14. Fourthly, because an electrode cannot be fabricated to have an appropriate thickness, so the resistance of the electrode is large in a big-size display. Such a large resistance may result in a problem associated with an unequal voltage drop, and therefore degrades the performance of a display.

Accordingly, it is desirable to have a structure for encapsulating the OLED display, which effectively resolves the foregoing problems associated with the conventional design.

### SUMMARY OF THE INVENTION

The object of the invention is to provide an encapsulating structure of the organic light emitting diode (OLED) display that has a satisfied stiffness against bending.

It is therefore another objective of the present invention to provide an encapsulating structure of the OLED display for reducing the resistance of the OLED cathode.

The present invention provides an OLED display comprising a substrate, an OLED device fabricated on a lower surface of the substrate, a back plate, and a metal pattern formed on an upper surface of the back plate that faces the lower surface of the substrate. The metal pattern is electrically connected with the cathode of the OLED device so as to reduce the resistance of the OLED cathode and to reinforce the back plate.

### BRIEF DESCRIPTION OF THE DRAWINGS

FIG. 1 shows a conventional OLED device structure.

FIG. 2 shows a cross-sectional view of a conventional structure of a typical OLED display.

FIG. 3 shows an encapsulating structure of OLED display in accordance with the present invention.

FIG. 4A is a perspective view of a first embodiment of a back plate in accordance with the present invention.

FIG. 4B is a perspective view of a second embodiment of the back plate in accordance with the present invention.

FIG. 4C is a perspective view of a third embodiment of the back plate in accordance with the present invention.

FIG. 4D is a perspective view of a fourth embodiment of the back plate in accordance with the present invention.

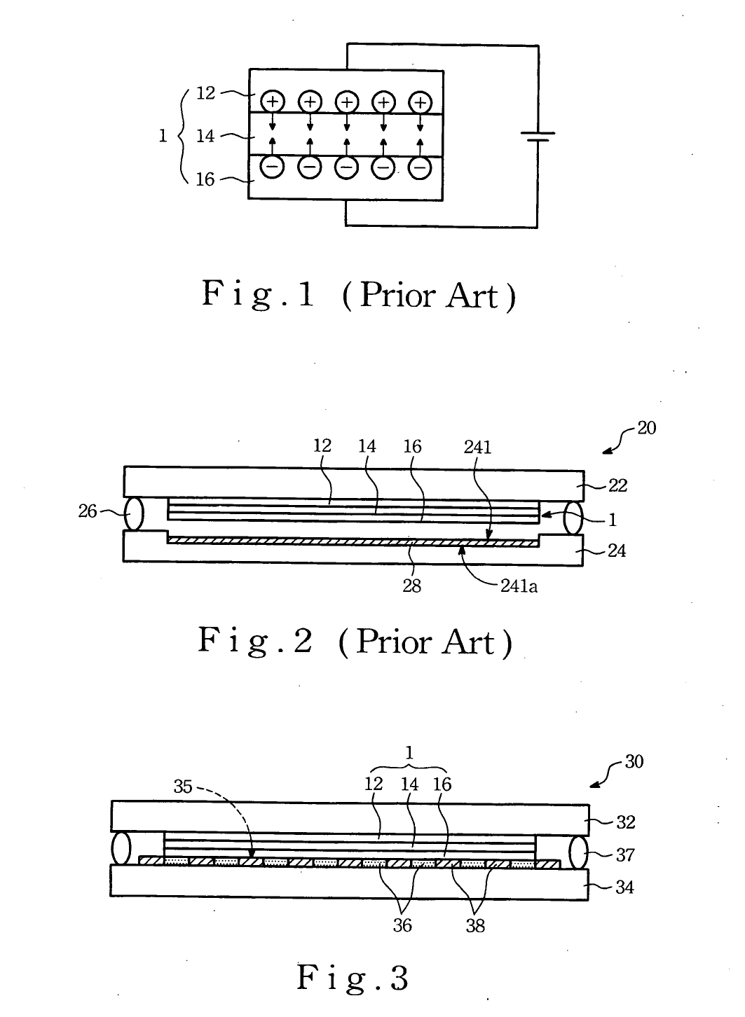

### DETAILED DESCRIPTION OF THE PREFERRED EMBODIMENT

FIG. 3 shows a preferred embodiment of an encapsulating structure of the OLED display in accordance with the present invention. The encapsulating structure of the OLED display 30 comprises an electroluminescence device 1 which can be an OLED, a metal pattern 36, a desiccant material 38, a substrate 32, and a back plate 34. The substrate 32 and the back plate 34 can be made from transparent panels such as glass panels.

The OLED 1 is fabricated on a lower surface of the substrate 32 which faces the back plate 34. The metal pattern 36 and the desiccant material 38 are formed on an upper surface of the back plate 34 which faces the substrate 32, and the desiccant material 38 is placed into cavity space 35 of the metal pattern 36, or in the spacing between the metal pattern 36 and a bordering adhesive 37. The substrate 32 is adhered to the back plate 34 by the adhesive 37, which runs around the edge of the back plate 34. By providing the substrate 32, the back plate 34 and the adhesive 37, a closed room for accommodating the OLED 1, the desiccant material 38, and the metal pattern 36 can be formed. The metal pattern 36 is fully or partial contacted with a cathode 16 of the OLED 1.

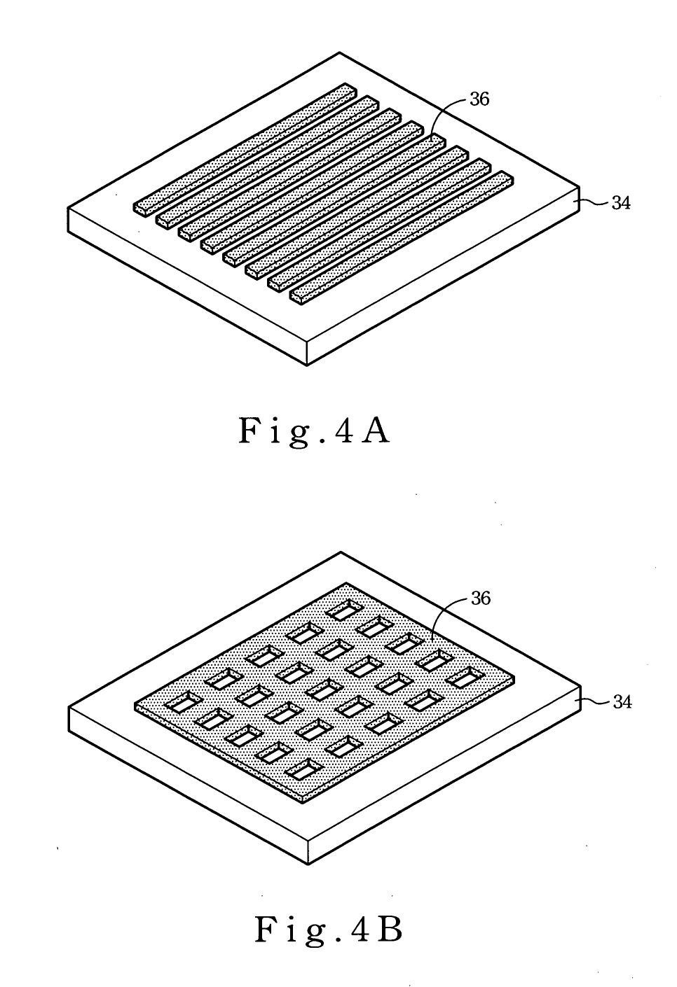

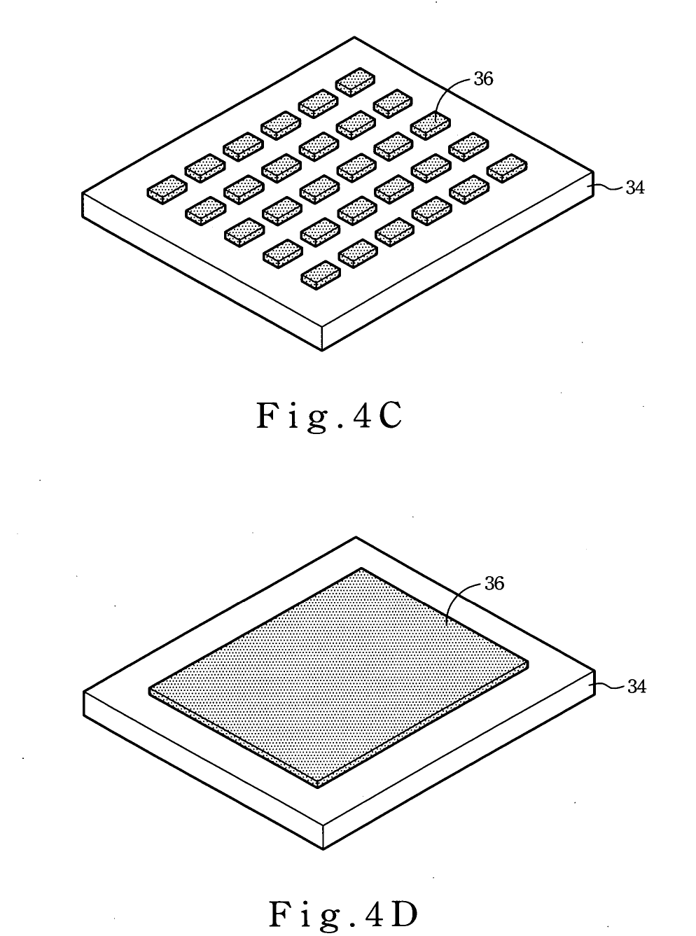

Referring to FIGS. 4A-4D, four embodiments-of the metal pattern 36 on the back plate 34 in accordance with the present invention are shown. The metal pattern 36 can be formed as parallel strips (FIG. 4A), lattices (FIG. 4B), pillar matrices (FIG. 4C), or a thin film (FIG. 4D). The metal pattern can be applied to a double or single emission devices when it is formed as a pattern of the parallel strips, the lattices, or the pillar matrices. On the other hand, when the metal pattern is a thin film, it can be applied to a bottom emission device.

According to the present invention, a method for encapsulating the OLED display is illustrated as follows. A back plate is provided and a metal pattern is formed on the back plate. The electroluminescence devices are fabricated on the lower surface of the substrate. The adhesive is coated around the back plate. The desiccant material is placed into cavity space of the metal pattern or the spacing between the metal pattern and a bordering adhesive. Thus, the substrate is adhered to the back plate by the adhesive, which runs around the edge of the back plate, so that the cathode of the electroluminescence devices contact with the metal pattern.

Various advantages, as follows, from using the metal pattern of the present invention can be obtained. Firstly, the metal pattern connected with the cathode of the electroluminescence device can be used as an extension of the cathode of the electroluminescence device due to the excellent electric conductivity of the metal. The metal pattern can be treated as to increase the cathode thickness, such that the resistance of the device can be reduced and the related voltage drop problem can be lessened. Secondly, the metal pattern acts as the reinforced structure to increase the bending strength of the back plate, and therefore the metal pattern directly connects with the electroluminescence device and carries both the substrate and the device. Further, it is not necessary for the back plate of the present invention to be machined to form a fillister for accommodating the desiccant material, so the strength and stiffness of the back plate can be sustained. Therefore, the cost of the back plate can be reduced. Thirdly, when the metal pattern is formed as strips, lattices, or pillar matrices, it can be used as a black matrix for the top emitting electroluminescence devices. The metal pattern can then reject the light at the portion other than the apertures (effective area) so as to raise the contrast ratio and to prevent blending color from contiguous pixels.

In general, the control circuit of electroluminescence device and other components are fabricated on the lower surface of the substrate. In the case that the electroluminescence device is a product of the top emission mode, several advantages such as raising the aperture ratio of the electroluminescence device, improving the contrast ratio, increasing the structure strength of the display, reducing the resistance of the cathode, improving the voltage drop problem, and making better uniformity of the display can be obtained.

While the invention has been particularly shown and described with reference to various embodiments, it will be recognized by those skilled in the art that modifications and changes may be made to the present invention without departing from the spirit and scope thereof. The scope of the invention should therefore be determined not with reference to the above description but with reference to the appended claims along with their full scope of equivalents.

What is claimed is:

1. An organic light emitting diode (OLED) display comprising:
a substrate;
a back plate;
an electroluminescence device fabricated on a lower surface of the substrate and located between the substrate and the back plate; and
a metal pattern formed on a surface of the back plate that faces the substrate and contacted with a cathode of the electroluminescence device.

2. The display of claim 1, wherein the substrate and the back plate are made of a transparent material.

3. The display of claim 2, wherein the transparent material is glass.

4. The display of claim 1, wherein the metal pattern is a pattern of parallel stripes.

5. The display of claim 1, wherein the metal pattern is a pattern of lattices.

6. The display of claim 1, wherein the metal pattern is a pattern of pillar matrices.

7. The display of claim 1, further comprising a desiccant material placed around the back plate.

8. The display of claim 1, further comprising a desiccant material placed in cavity space of the metal pattern.

9. A method for encapsulating an organic light emitting diode (OLED) display, comprising:
providing a back plate;
forming a metal pattern on the back plate;
coating an adhesive around the back plate; and
adhering a substrate to the back plate, wherein an electroluminescence device is fabricated on a lower surface of the substrate and a cathode of the electroluminescence device contacts with the metal pattern.

10. The method of claim 9, further comprising forming a desiccant material around the back plate.

11. The method of claim 9, further comprising forming a desiccant material in cavity space of the metal pattern.
